(19) United States
(12) Patent Application Publication
(10) Pub. No.: US 2026/0109638 A1
(43) Pub. Date: Apr. 23, 2026

(54) PLASMA-RESISTANT GLASS, INNER CHAMBER COMPONENT FOR SEMICONDUCTOR MANUFACTURING PROCESS AND METHODS FOR MANUFACTURING GLASS AND COMPONENT

(71) Applicant: HANSOL IONES CO., LTD., Gyeonggi-do (KR)

(72) Inventors: Seo Yeon JEON, Gyeonggi-do (KR); Kyung Min LEE, Gyeonggi-do (KR); Hye Won SEOK, Seoul (KR); Dae Gean KIM, Gyeonggi-do (KR)

(21) Appl. No.: 19/116,612

(22) PCT Filed: Aug. 18, 2023
(86) PCT No.: PCT/KR2023/012285

§ 371 Date: Mar. 28, 2025

(30) Foreign Application Priority Data
Oct. 13, 2022 (KR) 10-2022-0131087
Aug. 16, 2023 (KR) 10-2023-0106815

(51) Int. Cl. C03C 3/085; C03C 3/062; C03C 4/00; H01J 37/32

(52) U.S. Cl. CPC C03C 3/085; C03C 3/062; C03C 4/0092; H01J 37/32467; C03C 2201/54; C03C 2203/10; C03C 2203/52

(57) ABSTRACT

The present disclosure relates to plasma-resistant glass, an inner chamber component for a semiconductor manufacturing process, and methods for manufacturing the glass and the component, and specifically, to plasma-resistant glass, an inner chamber component for a semiconductor manufacturing process, and methods for manufacturing the glass and the component, wherein the contents of plasma-resistant glass components in the plasma-resistant glass are adjusted and SrO is added to achieve a lower melting temperature, the thermal expansion coefficient of the plasma-resistant glass is reduced to prevent damage from thermal shock during high-temperature use, and the plasma-resistant glass has improved light transmittance and durability.

### TECHNICAL FIELD

The present disclosure claims priority to and the benefits of Korean Patent Application No. 10-2022-0131087, filed with the Korean Intellectual Property Office on Oct. 13, 2022, the entire contents of which are incorporated herein by reference.

The present disclosure relates to plasma-resistant glass, an inner chamber component for a semiconductor manufacturing process, and methods for manufacturing the glass and the component, and specifically, to plasma-resistant glass, an inner chamber component for a semiconductor manufacturing process, and methods for manufacturing the glass and the component, wherein the contents of plasma-resistant glass components in the plasma-resistant glass are adjusted and SrO is added to achieve a lower melting temperature, the thermal expansion coefficient of the plasma-resistant glass is reduced to prevent damage from thermal shock during high-temperature use, and the plasma-resistant glass has improved light transmittance and durability.

### BACKGROUND ART

A plasma etching process is used when manufacturing semiconductors and/or displays. With the recent use of a nano-process, difficulty of etching increases, and oxide-based ceramics having corrosion resistance such as alumina (Al₂O₃) and yttria (Y₂O₃) are mainly used for inner components of a process chamber exposed to a high-density plasma environment.

When a polycrystal material is exposed to a high-density plasma etching environment using fluorine-based gas for a long period of time, particles are eliminated due to local erosion, which increases the probability of contaminant particle generation. This causes defects in semiconductors/displays, and adversely affects production yields. In addition, oxide-based ceramic materials have a problem of low workability due to a high melting temperature.

Accordingly, there is a need to develop a technology capable of preventing damage to existing plasma-resistant glass caused by thermal shock while having a low melting temperature.

### DISCLOSURE

### Technical Problem

The present disclosure is directed to providing plasma-resistant glass, an inner chamber component for a semiconductor manufacturing process, and methods for manufacturing the glass and the component, wherein the plasma-resistant glass has excellent resistance by plasma inside a chamber used in a semiconductor manufacturing process, has excellent heat resistance under a high-temperature condition, thereby preventing damage to the component used inside a chamber, and is capable of achieving a low melting temperature.

However, problems to be solved by the present disclosure are not limited to the above-mentioned problem, and other problems not mentioned will be clearly understood by those skilled in the art from the following description.

### Technical Solution

One embodiment of the present disclosure provides plasma-resistant glass formed by melting a composition including 30% by weight or greater and 80% by weight or less of SiO₂, 5% by weight or greater and 35% by weight or less of Al₂O₃ and 10% by weight or greater and 50% by weight or less of SrO.

According to one embodiment of the present disclosure, the composition includes only SiO₂, Al₂O₃, SrO and inevitable impurities, and the content of the SiO₂ may be 30% by weight or greater and 68% by weight or less, the content of the Al₂O₃ may be 5% by weight or greater and 25% by weight or less and the content of the SrO may be 15% by weight or greater and 50% by weight or less.

According to one embodiment of the present disclosure, the plasma-resistant glass may have light transmittance of 80% or greater and 100% or less.

According to one embodiment of the present disclosure, the plasma-resistant glass may have Vickers hardness of 650 HV or greater and 1,000 HV or less.

According to one embodiment of the present disclosure, the plasma-resistant glass may have a glass transition temperature of 600° C. or higher and 850° C. or lower.

According to one embodiment of the present disclosure, the plasma-resistant glass may have a thermal expansion coefficient of 4.0×10⁻⁶ m/(m° C.) or greater and 6.0×10⁻⁶ m/(m° C.) or less.

According to one embodiment of the present disclosure, the plasma-resistant glass may have an etching rate by mixed plasma of fluorine and argon (Ar) of greater than 0 nm/min and 20 nm/min or less.

According to one embodiment of the present disclosure, the plasma-resistant glass may have a melting point of 1,500° C. or higher and 1,750° C. or lower.

One embodiment of the present disclosure provides an inner chamber component for a semiconductor manufacturing process manufactured with the plasma-resistant glass.

According to one embodiment of the present disclosure, the inner chamber component may be any one of a focus ring, an edge ring, a cover ring, a ring shower, an insulator, an EPD window, an electrode, a view port, an inner shutter, an electro static chuck, a heater, a chamber liner, a shower head, a boat for CVD (chemical vapor deposition), a wall liner, a shield, a cold pad, a source head, an outer liner, a deposition shield, an upper liner, an exhaust plate and a mask frame.

One embodiment of the present disclosure provides a method for manufacturing plasma-resistant glass, the method including: melting a composition including 30% by weight or greater and 80% by weight or less of SiO₂, 5% by weight or greater and 35% by weight or less of Al₂O₃ and 10% by weight or greater and 50% by weight or less of SrO; and cooling the melted composition.

According to one embodiment of the present disclosure, a melting temperature in the melting of a composition may be 1,400° C. or higher and 1,700° C. or lower.

One embodiment of the present disclosure provides a method for manufacturing an inner chamber component for a semiconductor manufacturing process, the method including: melting the plasma-resistant glass; injecting the melted plasma-resistant glass into a mold; and annealing the injected plasma-resistant glass.

According to one embodiment of the present disclosure, a melting temperature in the melting of the plasma-resistant glass may be 1,500° C. or higher and 1,750° C. or lower.

According to one embodiment of the present disclosure, a temperature in the annealing may be 400° C. or higher and 900° C. or lower.

### Advantageous Effects

Plasma-resistant glass according to one embodiment of the present disclosure is capable of improving processability by achieving a low melting temperature, and readily manufacturing an inner chamber component for a semiconductor manufacturing process.

The plasma-resistant glass according to one embodiment of the present disclosure exhibits low thermal expansion coefficient properties, and therefore, is capable of preventing damage caused by thermal shock under a high-temperature atmosphere.

The plasma-resistant glass according to one embodiment of the present disclosure has improved light transmittance, and improved mechanical properties by improving hardness, and therefore, is capable of improving durability in a plasma etching environment.

An inner chamber component for a semiconductor manufacturing process according to one embodiment of the present disclosure is capable of improving hours of use in a semiconductor manufacturing process by achieving a low etching rate for plasma, and is capable of improving durability by preventing damage to the component caused by thermal shock.

A method for manufacturing plasma-resistant glass according to one embodiment of the present disclosure readily manufactures plasma-resistant glass, and is capable of preventing damage caused by thermal shock under a high-temperature atmosphere.

A method for manufacturing an inner chamber component for a semiconductor manufacturing process according to one embodiment of the present disclosure is capable of manufacturing a component having various shapes, preventing damage caused by thermal shock under a high-temperature atmosphere, and readily manufacturing the component.

Effects of the present disclosure are not limited to the above-described effects, and effects not mentioned herein will be clearly appreciated by those skilled in the art from the present specification and accompanying drawings.

### BRIEF DESCRIPTION OF DRAWINGS

FIG. 1 is a flow chart of a method for manufacturing plasma-resistant glass according to one embodiment of the present disclosure.

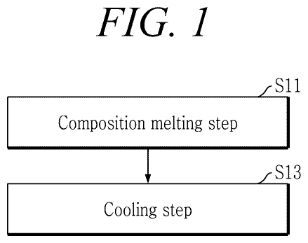

FIG. 2 is a flow chart of a method for manufacturing an inner chamber component for a semiconductor manufacturing process according to one embodiment of the present disclosure.

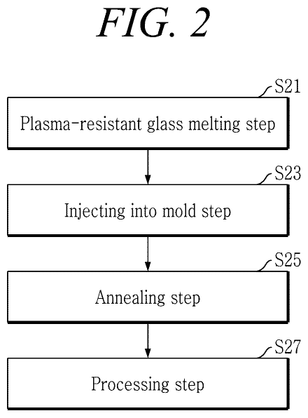

FIG. 3 shows photographs of plasma-resistant glass of Examples 1 to 8, which are embodiments of the present disclosure, and Comparative Examples 1 and 2.

### REFERENCE NUMERAL

S11: Composition melting step
S13: Cooling step
S21: Plasma-resistant glass melting step
S23: Injecting into mold step
S25: Annealing step
S27: Processing step

### BEST MODE

Throughout the present specification, a description of a certain part “including” certain components means that it may further include other components, and does not exclude other components unless particularly stated on the contrary.

Throughout the specification, “A and/or B” means “A and B, or A or B”.

Hereinafter, the present disclosure will be described in more detail.

One embodiment of the present disclosure provides plasma-resistant glass formed by melting a composition including 30% by weight or greater and 80% by weight or less of SiO₂, 5% by weight or greater and 35% by weight or less of Al₂O₃ and 10% by weight or greater and 50% by weight or less of SrO.

The plasma-resistant glass according to one embodiment of the present disclosure is capable of improving processability by achieving a low melting temperature, readily manufacturing an inner chamber component for a semiconductor manufacturing process, and preventing damage caused by thermal shock under a high-temperature atmosphere by exhibiting low thermal expansion coefficient properties, and has improved light transmittance and improved mechanical properties by improving hardness, thereby improving durability in a plasma etching environment.

According to one embodiment of the present disclosure, the composition includes 30% by weight or greater and 80% by weight or less of SiO₂. Specifically, the content of SiO₂ in the composition may be 31% by weight or greater and 79% by weight or less, 32% by weight or greater and 78% by weight or less, 33% by weight or greater and 77% by weight or less, 34% by weight or greater and 76% by weight or less, 35% by weight or greater and 75% by weight or less, 36% by weight or greater and 74% by weight or less, 37% by weight or greater and 73% by weight or less, 38% by weight or greater and 72% by weight or less, 39% by weight or greater and 71% by weight or less, 40% by weight or greater and 70% by weight or less, 41% by weight or greater and 69% by weight or less, 42% by weight or greater and 68% by weight or less, 43% by weight or greater and 67% by weight or less, 44% by weight or greater and 66% by weight or less, 45% by weight or greater and 65% by weight or less, 46% by weight or greater and 64% by weight or less, 47% by weight or greater and 63% by weight or less, 48% by weight or greater and 62% by weight or less, 49% by weight or greater and 61% by weight or less, 50% by weight or greater and 60% by weight or less, 51% by weight or greater and 59% by weight or less, 52% by weight or greater and 58% by weight or less, 53% by weight or greater and 57% by weight or less or 54% by weight or greater and 56% by weight or less. By including the SiO₂ and adjusting the SiO₂ content in the above-described range as described above, basic properties of the plasma-resistant glass may be secured, durability and reliability may be improved, and production costs of components may be reduced by facilitating the processing of the plasma-resistant glass.

According to one embodiment of the present disclosure, the composition includes 5% by weight or greater and 35% by weight or less of Al₂O₃. Specifically, the content of Al₂O₃ in the composition may be 6% by weight or greater and 34% by weight or less, 7% by weight or greater and 33% by weight or less, 8% by weight or greater and 32% by weight or less, 9% by weight or greater and 31% by weight or less, 10% by weight or greater and 30% by weight or less, 11% by weight or greater and 29% by weight or less, 12% by weight or greater and 28% by weight or less, 13% by weight or greater and 27% by weight or less, 14% by weight or greater and 26% by weight or less, 15% by weight or greater and 25% by weight or less, 16% by weight or greater and 24% by weight or less, 17% by weight or greater and 23% by weight or less, 18% by weight or greater and 22% by weight or less or 19% by weight or greater and 21% by weight or less. By including the Al₂O₃ and adjusting the Al₂O₃ content in the above-described range as described above, outgassing may be prevented, generation of particles may also be suppressed, wear resistance of an inner chamber component for a semiconductor manufacturing process may be improved, and the composition may be readily melted by lowering a melting temperature of the composition even when SrO to be described later is included.

According to one embodiment of the present disclosure, the composition includes 10% by weight or greater and 50% by weight or less of SrO. Specifically, the content of SrO in the composition may be 11% by weight or greater and 49% by weight or less, 12% by weight or greater and 48% by weight or less, 13% by weight or greater and 47% by weight or less, 14% by weight or greater and 46% by weight or less, 15% by weight or greater and 45% by weight or less, 16% by weight or greater and 44% by weight or less, 17% by weight or greater and 43% by weight or less, 18% by weight or greater and 42% by weight or less, 19% by weight or greater and 41% by weight or less, 20% by weight or greater and 40% by weight or less, 21% by weight or greater and 39% by weight or less, 22% by weight or greater and 38% by weight or less, 23% by weight or greater and 37% by weight or less, 24% by weight or greater and 36% by weight or less, 25% by weight or greater and 35% by weight or less, 26% by weight or greater and 34% by weight or less, 27% by weight or greater and 33% by weight or less, 28% by weight or greater and 32% by weight or less or 29% by weight or greater and 31% by weight or less. By including the SrO, adjusting the SrO content in the above-described range as described above to achieve low thermal expansion coefficient and low glass transition temperature for the glass, thermal shock at a high temperature may be minimized, and durability of an inner chamber component for a semiconductor manufacturing process may be improved.

According to one embodiment of the present disclosure, the plasma-resistant glass is formed by melting the composition. By forming the plasma-resistant glass through melting and then cooling the composition as described above, the plasma-resistant glass may be readily formed by melting the composition at a relatively low temperature, and breakage caused by thermal shock may be prevented.

According to one embodiment of the present disclosure, the plasma-resistant glass may have a dielectric constant of 6.65 or greater and 8.10 or less. Specifically, the plasma-resistant glass may have a dielectric constant of 6.70 or greater and 8.05 or less, 6.75 or greater and 8.00 or less, 6.80 or greater and 7.95 or less, 6.85 or greater and 7.90 or less, 6.90 or greater and 7.85 or less, 6.95 or greater and 7.80 or less, 7.00 or greater and 7.75 or less, 7.05 or greater and 7.70 or less, 7.10 or greater and 7.65 or less, 7.15 or greater and 7.60 or less, 7.20 or greater and 7.55 or less, 7.25 or greater and 7.50 or less, 7.30 or greater and 7.45 or less or 7.35 or greater and 7.40 or less. More specifically, the plasma-resistant glass may have a dielectric constant of 6.79 or greater and 6.99 or less, 6.79 or greater and 7.19 or less, 6.79 or greater and 7.39 or less, 6.79 or greater and 7.59 or less, 6.99 or greater and 7.19 or less, 6.99 or greater and 7.39 or less, 6.99 or greater and 7.59 or less, 7.19 or greater and 7.39 or less, 7.19 or greater and 7.59 or less or 7.39 or greater and 7.59 or less. Methods of measuring the dielectric constant include a capacitance method using an LCR meter, a reflection coefficient method using a network analyzer, a resonant frequency method and the like. As an example of the methods of measuring the dielectric constant, a capacitance method using an LCR meter is mainly used to measure low frequency properties (kHZ, MHz), and a dielectric constant may be determined from physical size and capacitance of a capacitor. By obtaining the dielectric constant of the plasma-resistant glass in the above-described range, thermal shock at a high temperature may be minimized, durability of an inner chamber component for a semiconductor manufacturing process may be improved, and light transmittance and durability may be improved.

According to one embodiment of the present disclosure, the composition may include only SiO₂, Al₂O₃, SrO and inevitable impurities. By controlling the components of the composition as described above, a low melting temperature may be achieved, and crystallization may be prevented.

According to one embodiment of the present disclosure, the composition may not include an organic binder and/or a solvent. By the composition not including an organic binder and/or a solvent as described above, impurities may be minimized, low light transmittance may be secured, and a low etching rate may be obtained.

According to one embodiment of the present disclosure, the content of SiO₂ may be 30% by weight or greater and 68% by weight or less in the composition. By adjusting the SiO₂ content in the above-described range, basic properties of the plasma-resistant glass may be secured, durability and reliability may be improved, and production costs of components may be reduced by facilitating the processing of the plasma-resistant glass.

According to one embodiment of the present disclosure, the content of Al₂O₃ may be 5% by weight or greater and 25% by weight or less in the composition. By adjusting the Al₂O₃ content in the above-described range, outgassing may be prevented, generation of particles may also be suppressed, wear resistance of an inner chamber component for a semiconductor manufacturing process may be improved, and the composition may be readily melted by lowering a melting temperature of the composition even when SrO to be described later is included.

According to one embodiment of the present disclosure, the content of SrO may be 15% by weight or greater and 50% by weight or less in the composition. By including the SrO, adjusting the SrO content in the above-described range as described above to achieve low thermal expansion coefficient and low glass transition temperature for the glass, thermal shock at a high temperature may be minimized, and durability of an inner chamber component for a semiconductor manufacturing process may be improved.

According to one embodiment of the present disclosure, the plasma-resistant glass may have light transmittance of 80% or greater and 100% or less. Specifically, the plasma-resistant glass may have light transmittance of 82% or greater and 98% or less, 85% or greater and 95% or less or 87% or greater and 92% or less. In the present specification, “light transmittance” may mean a value measured using a haze meter (JCH-300S, Ocean Optics). By the plasma-resistant glass having light transmittance in the above-described range, high vitrification may be achieved while improving the degree of melting of the plasma-resistant glass.

According to one embodiment of the present disclosure, the plasma-resistant glass may have Vickers hardness of 650 HV or greater and 1,000 HV or less. Specifically, the plasma-resistant glass may have Vickers hardness of 670 HV or greater and 980 HV or less, 650 HV or greater and 950 HV or less, 680 HV or greater and 930 HV or less, 700 HV or greater and 900 HV or less, 720 HV or greater and 880 HV or less, 750 HV or greater and 850 HV or less or 780 HV or greater and 820 HV or less. In the present specification, “Vickers hardness” may mean a value measured using a Vickers hardness tester (FISCHERSCOPE HM-2000, Helmut Fischer GmbH). By the plasma-resistant glass having Vickers hardness in the above-described range, mechanical properties are improved, and durability in a plasma etching environment may be improved.

According to one embodiment of the present disclosure, the plasma-resistant glass may have a glass transition temperature of 600° C. or higher and 850° C. or lower. Specifically, the plasma-resistant glass may have a glass transition temperature of 620° C. or higher and 830° C. or lower, 650° C. or higher and 800° C. or lower, 670° C. or higher and 780° C. or lower or 700° C. or higher and 750° C. or lower. By adjusting the glass transition temperature of the plasma-resistant glass in the above-described range, thermal shock of an inner chamber component for a semiconductor manufacturing process at a high temperature may be minimized, and durability may be improved.

According to one embodiment of the present disclosure, the plasma-resistant glass may have a thermal expansion coefficient of 4.0×10⁻⁶ m/(m° C.) or greater and 6.0×10⁻⁶ m/(m° C.) or less. Specifically, the plasma-resistant glass may have a thermal expansion coefficient of 4.1×10⁻⁶ m/(m° C.) or greater and 5.9×10⁻⁶ m/(m° C.) or less, 4.2×10⁻⁶ m/(m° C.) or greater and 5.8×10⁻⁶ m/(m° C.) or less, 4.3×10⁻⁶ m/(m° C.) or greater and 5.7×10⁻⁶ m/(m° C.) or less, 4.4×10⁻⁶ m/(m° C.) or greater and 5.6×10⁻⁶ m/(m° C.) or less, 4.5×10⁻⁶ m/(m° C.) or greater and 5.5×10⁻⁶ m/(m° C.) or less, 4.6×10⁻⁶ m/(m° C.) or greater and 5.4×10⁻⁶ m/(m° C.) or less, 4.7×10⁻⁶ m/(m° C.) or greater and 5.3×10⁻⁶ m/(m° C.) or less, 4.8×10⁻⁶ m/(m° C.) or greater and 5.2×10⁻⁶ m/(m° C.) or less or 4.9×10⁻⁶ m/(m° C.) or greater and 5.1×10⁻⁶ m/(m° C.) or less. By adjusting the thermal expansion coefficient of the plasma-resistant glass in the above-described range, durability may be improved by preventing damage to the component caused by thermal shock.

According to one embodiment of the present disclosure, the plasma-resistant glass may have an etching rate by mixed plasma of fluorine and argon (Ar) of greater than 0 nm/min and 20 nm/min or less. Specifically, the plasma-resistant glass may have an etching rate by mixed plasma of fluorine and argon (Ar) of greater than 0 nm/min and 18 nm/min or less, 1 nm/min or greater and 16 nm/min or less, 2 nm/min or greater and 15 nm/min or less, 3 nm/min or greater and 14 nm/min or less, 4 nm/min or greater and 13 nm/min or less, 5 nm/min or greater and 12 nm/min or less, 6 nm/min or greater and 11 nm/min or less or 7 nm/min or greater and 10 nm/min or less. By obtaining the etching rate by mixed plasma of fluorine and argon (Ar) in the above-described range, the inner chamber component for a semiconductor manufacturing process achieves a low etching rate for plasma, and hours of use may be improved in a semiconductor manufacturing process.

According to one embodiment of the present disclosure, the plasma-resistant glass may have an etching step of 150 nm or greater and 400 nm or less. Specifically, the plasma-resistant glass may have an etching step of 160 nm or greater and 390 nm or less, 170 nm or greater and 380 nm or less, 180 nm or greater and 370 nm or less or 190 nm or greater and 360 nm or less. By the plasma-resistant glass having an etching step in the above-described range, the inner chamber component for a semiconductor manufacturing process achieves a low etching rate for plasma, and hours of use may be improved in a semiconductor manufacturing process.

According to one embodiment of the present disclosure, the plasma-resistant glass may have a melting point of 1,500° C. or higher and 1,750° C. or lower. In the present specification, the melting point may mean a melting temperature. Specifically, the plasma-resistant glass may have a melting point of 1,560° C. or higher and 1,740° C. or lower, 1,570° C. or higher and 1,730° C. or lower, 1,580° C. or higher and 1,720° C. or lower, 1,590° C. or higher and 1,710° C. or lower, 1,600° C. or higher and 1,700° C. or lower, 1,610° C. or higher and 1,690° C. or lower, 1,620° C. or higher and 1,680° C. or lower, 1,630° C. or higher and 1,670° C. or lower or 1,640° C. or higher and 1,660° C. or lower. By adjusting the melting point of the plasma-resistant glass in the above-described range, viscosity of the melt of the plasma-resistant glass is controlled, and workability of a process using the plasma-resistant glass may be improved.

According to one embodiment of the present disclosure, the plasma-resistant glass may be amorphous. By the plasma-resistant glass having an amorphous structure as described above, an etching rate by plasma may be reduced while improving durability of components using the plasma-resistant glass.

One embodiment of the present disclosure provides an inner chamber component for a semiconductor manufacturing process manufactured with the plasma-resistant glass.

The inner chamber component for a semiconductor manufacturing process according to one embodiment of the present disclosure achieves a low etching rate for plasma, thereby improving hours of use in a semiconductor manufacturing process, and may improve durability by preventing damage to the component caused by thermal shock.

According to one embodiment of the present disclosure, the inner chamber component may be any one of a focus ring, an edge ring, a cover ring, a ring shower, an insulator, an EPD window, an electrode, a view port, an inner shutter, an electro static chuck, a heater, a chamber liner, a shower head, a boat for CVD (chemical vapor deposition), a wall liner, a shield, a cold pad, a source head, an outer liner, a deposition shield, an upper liner, an exhaust plate and a mask frame. By using the inner chamber component from those described above, hours of use may be extended by improving resistance to plasma in the semiconductor manufacturing process, minimizing costs required for semiconductor manufacturing.

One embodiment of the present disclosure provides a method for manufacturing plasma-resistant glass, the method including: melting a composition including 30% by weight or greater and 80% by weight or less of SiO₂, 5% by weight or greater and 35% by weight or less of Al₂O₃ and 10% by weight or greater and 50% by weight or less of SrO; and cooling the melted composition.

The method for manufacturing plasma-resistant glass according to one embodiment of the present disclosure readily manufactures plasma-resistant glass, preventing damage caused by thermal shock under a high-temperature atmosphere, and improves mechanical properties by manufacturing glass with higher hardness than existing glass, thereby improving durability in a plasma etching environment.

In the method for manufacturing plasma-resistant glass, which is one embodiment of the present disclosure, description overlapping the description provided in the plasma-resistant glass is not included.

According to one embodiment of the present disclosure, the method for manufacturing plasma-resistant glass includes melting a composition including 30% by weight or greater and 80% by weight or less of SiO₂, 5% by weight or greater and 35% by weight or less of Al₂O₃ and 10% by weight or greater and 50% by weight or less of SrO (S11). By controlling the components of the plasma-resistant glass and adjusting the content of the components as described above, damage to the plasma-resistant glass caused by thermal shock may be prevented under a high-temperature atmosphere, a low melting temperature may be achieved, and light transmittance and durability may be improved.

According to one embodiment of the present disclosure, the melting may be melting the composition by placing it in a platinum crucible. By melting the composition in a platinum crucible as described above, components eluted from the crucible are minimized, and properties of the plasma-resistant glass may be obtained.

According to one embodiment of the present disclosure, the method for manufacturing plasma-resistant glass includes cooling the melted glass composition (S13). By including the cooling of the melted glass composition as described above, crystals of the plasma-resistant glass are controlled, and breakage caused by sudden thermal change may be prevented.

According to one embodiment of the present disclosure, the temperature in the cooling may be room temperature. By adjusting the temperature in the cooling in the above-described range, crystals of the plasma-resistant glass may be controlled, and the melting during the process for manufacturing the inner chamber component for a semiconductor manufacturing process may be readily performed.

According to one embodiment of the present disclosure, the melting temperature in the melting of the composition may be 1,400° C. or higher and 1,700° C. or lower. Specifically, as for the melting temperature in the melting of a composition, the melting point may be 1,400° C. or higher and 1,700° C. or lower. In the present specification, the melting point may mean a melting temperature. Specifically, the plasma-resistant glass may have a melting point of 1,500° C. or higher and 1,750° C. or lower, 1,560° C. or higher and 1,740° C. or lower, 1,570° C. or higher and 1,730° C. or lower, 1,580° C. or higher and 1,720° C. or lower, 1,590° C. or higher and 1,710° C. or lower, 1,600° C. or higher and 1,700° C. or lower, 1,610° C. or higher and 1,690° C. or lower, 1,620° C. or higher and 1,680° C. or lower, 1,630° C. or higher and 1,670° C. or lower or 1,640° C. or higher and 1,660° C. or lower. By adjusting the melting temperature in the melting of a composition in the above-mentioned range, viscosity of the melted composition is controlled, improving workability of the process for manufacturing plasma-resistant glass.

One embodiment of the present disclosure provides a method for manufacturing an inner chamber component for a semiconductor manufacturing process, the method including: melting the plasma-resistant glass; injecting the melted plasma-resistant glass into a mold; and annealing the injected plasma-resistant glass.

The method for manufacturing an inner chamber component for a semiconductor manufacturing process according to one embodiment of the present disclosure is capable of manufacturing a component having various shapes, preventing damage caused by thermal shock under a high-temperature atmosphere, and readily manufacturing the component.

According to one embodiment of the present disclosure, the method for manufacturing an inner chamber component for a semiconductor manufacturing process includes melting the plasma-resistant glass (S21). By including the melting of the plasma-resistant glass as described above, workability of the process for manufacturing an inner chamber component for a semiconductor manufacturing process is improved, and at the same time, the component may be molded into various shapes by injecting a molten metal obtained by melting the plasma-resistant glass into a mold.

According to one embodiment of the present disclosure, the method for manufacturing an inner chamber component for a semiconductor manufacturing process includes injecting the melted plasma-resistant glass into a mold (S23). By injecting the melted plasma-resistant glass into a mold as described above, a component having various shapes may be manufactured.

According to one embodiment of the present disclosure, the mold may have any one shape of a focus ring, an edge ring, a cover ring, a ring shower, an insulator, an EPD window, an electrode, a view port, an inner shutter, an electro static chuck, a heater, a chamber liner, a shower head, a boat for CVD (chemical vapor deposition), a wall liner, a shield, a cold pad, a source head, an outer liner, a deposition shield, an upper liner, an exhaust plate and a mask frame. By the mold having various shapes as described above, the manufacturing time may be reduced by readily obtaining the component shape.

According to one embodiment of the present disclosure, the method for manufacturing an inner chamber component for a semiconductor manufacturing process includes annealing the injected plasma-resistant glass (S25). By including the annealing of the injected plasma-resistant glass as described above, stress caused by heat generated in the component manufactured by being injected into the mold is minimized, and as a result, durability of the component is improved, and thermal shock at a high temperature may be minimized.

According to one embodiment of the present disclosure, the melting temperature in the melting of the plasma-resistant glass may be 1,500° C. or higher and 1,750° C. or lower. Specifically, the melting temperature in the melting of the plasma-resistant glass may be 1,500° C. or higher and 1,750° C. or lower. In the present specification, the melting point may mean a melting temperature. Specifically, the plasma-resistant glass may have a melting point of 1,560° C. or higher and 1,740° C. or lower, 1,570° C. or higher and 1,730° C. or lower, 1,580° C. or higher and 1,720° C. or lower, 1,590° C. or higher and 1,710° C. or lower, 1,600° C. or higher and 1,700° C. or lower, 1,610° C. or higher and 1,690° C. or lower, 1,620° C. or higher and 1,680° C. or lower, 1,630° C. or higher and 1,670° C. or lower or 1,640° C. or higher and 1,660° C. or lower. By adjusting the melting temperature in the melting of the plasma-resistant glass in the above-mentioned range, workability may be improved by controlling viscosity of the melted plasma-resistant glass.

According to one embodiment of the present disclosure, the temperature in the annealing may be 400° C. or higher and 900° C. or lower. Specifically, the temperature in the annealing may be 430° C. or higher and 890° C. or lower, 450° C. or higher and 880° C. or lower, 470° C. or higher and 870° C. or lower, 500° C. or higher and 860° C. or lower, 550° C. or higher and 850° C. or lower, 560° C. or higher and 840° C. or lower, 570° C. or higher and 830° C. or lower, 580° C. or higher and 820° C. or lower, 590° C. or higher and 810° C. or lower, 600° C. or higher and 800° C. or lower, 610° C. or higher and 790° C. or lower, 620° C. or higher and 780° C. or lower, 630° C. or higher and 770° C. or lower, 640° C. or higher and 760° C. or lower, 650° C. or higher and 750° C. or lower, 660° C. or higher and 740° C. or lower, 670° C. or higher and 730° C. or lower, 680° C. or higher and 720° C. or lower or 690° C. or higher and 710° C. or lower. By adjusting the temperature in the annealing in the above-described range, stress caused by heat formed in the inner chamber component for a semiconductor manufacturing process is reduced, and durability of the component may be improved by minimizing thermal shock at a high temperature.

According to one embodiment of the present disclosure, the method for manufacturing an inner chamber component for a semiconductor manufacturing process may include processing the precursor of the inner chamber component for a semiconductor manufacturing process manufactured with the annealed plasma-resistant glass (S27). By processing the precursor of the inner chamber component for a semiconductor manufacturing process as described above, a sophisticated component may be manufactured.

Hereinafter, the present disclosure will be described in detail with reference to examples in order to specifically describe the present disclosure. However, examples according to the present disclosure may be modified to various different forms, and the scope of the present disclosure is not construed as being limited to the examples described below. Examples of the present specification are provided in order to more fully describe the present disclosure to those having average knowledge in the art.

### Example 1

A composition including 60% by weight of SiO₂, 20% by weight of Al₂O₃ and 20% by weight of SrO was prepared. Specifically, 600 g of the composition was prepared, and mixed for about 1 hour using a zirconia ball milling method. In other words, the composition was dry mixed by employing 600 g of the composition and 1,800 g of a zirconia ball (weight ratio 1:3), and then dried for 24 hours. After that, the temperature of the dried composition was raised at a rate of 10° C./min using a super kanthal furnace until the temperature reached 1,650° C., and the temperature of 1,650° C. was maintained for about 2 hours to prepare a melted composition.

After that, the melted composition was cooled to room temperature to manufacture plasma-resistant glass.

### Example 2

Plasma-resistant glass was manufactured in the same manner as in Example 1, except that the composition was prepared to include 45% by weight of SiO₂, 15% by weight of Al₂O₃ and 40% by weight of SrO, and the temperature of 1,650° C. was maintained for about 4 hours.

### Example 3

Plasma-resistant glass was manufactured in the same manner as in Example 1, except that the composition was prepared to include 60% by weight of SiO₂, 15% by weight of Al₂O₃ and 25% by weight of SrO, and the temperature of 1,650° C. was maintained for about 4 hours.

### Example 4

Plasma-resistant glass was manufactured in the same manner as in Example 1, except that the composition was prepared to include 65% by weight of SiO₂, 15% by weight of Al₂O₃ and 20% by weight of SrO.

### Example 5

Plasma-resistant glass was manufactured in the same manner as in Example 1, except that the composition was prepared to include 30% by weight of SiO₂, 25% by weight of Al₂O₃ and 45% by weight of SrO, and the temperature of 1,650° C. was maintained for about 4 hours.

### Example 6

Plasma-resistant glass was manufactured in the same manner as in Example 1, except that the composition was prepared to include 50% by weight of SiO₂, 5% by weight of Al₂O₃ and 45% by weight of SrO, and the temperature of 1,650° C. was maintained for about 4 hours.

### Example 7

Plasma-resistant glass was manufactured in the same manner as in Example 1, except that the composition was prepared to include 30% by weight of SiO₂, 25% by weight of Al₂O₃ and 45% by weight of SrO, and the temperature of 1,650° C. was maintained for about 5 hours.

### Example 8

Plasma-resistant glass was manufactured in the same manner as in Example 1, except that the composition was prepared to include 60% by weight of SiO₂, 25% by weight of Al₂O₃ and 15% by weight of SrO.

### Comparative Example 1

Plasma-resistant glass was manufactured in the same manner as in Example 1, except that the composition was prepared to include 40% by weight of SiO₂, 35% by weight of Al₂O₃ and 25% by weight of SrO, and the temperature of 1,650° C. was maintained for about 4 hours.

### Comparative Example 2

Plasma-resistant glass was manufactured in the same manner as in Example 1, except that the composition was prepared to include 40% by weight of SiO₂, 5% by weight of Al₂O₃ and 55% by weight of SrO, and the temperature of 1,650° C. was maintained for about 4 hours.

### Experimental Example 1: Measurement of Melted State of Plasma-Resistant Glass

The plasma-resistant glass of each of Examples 1 to 8 and Comparative Examples 1 and 2 was placed in a platinum crucible, and then heated for 4 hours under a condition of temperature of 1,650° C. and pressure of 1 atom. After that, the appearance was measured.

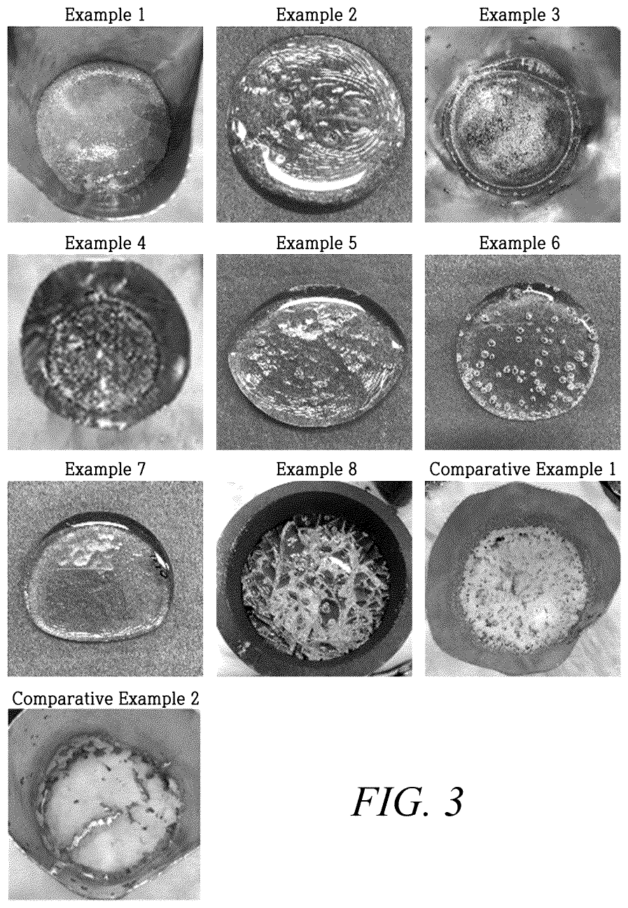

FIG. 3 shows photographs of the plasma-resistant glass of Examples 1 to 8, which are embodiments of the present disclosure, and Comparative Examples 1 and 2. Referring to FIG. 3, it was identified that the plasma-resistant glass of each of Examples 1 to 8 was melted and vitrified without unmelted portions. In contrast, it was identified that the plasma-resistant glass of each of Comparative Examples 1 and 2 was crystallized instead of being melted.

Accordingly, it was identified that, when the SrO is added to the composition, the Al₂O₃ content needs to be maintained in an appropriate range to lower a melting temperature, and to form a melt without crystallization.

### Experimental Example 2: Measurement of Dielectric Constant

For Reference Example 1 made of Quartz and Examples 6 and 8, a dielectric constant was measured at a measurement frequency of 1 MHz using a Keysight E4990A Impedance Analyzer, and the results are summarized in the following Table 1.

### Experimental Example 3: Measurement of Etching Step and Etching Rate

Each of Reference Example 1 made of Quartz and Examples 6 and 8 was partially exposed for 1 hour by mixed plasma of fluorine and argon (Ar), and an etching step, which is a difference between the portions exposed by the plasma and the unexposed portions, was measured using a confocal laser microscope (OLS 5100 equipment of Olympus Corporation, 400 magnification). The etching step was divided by the etching time to calculate an etching rate, and the results are summarized in the following Table 1.

TABLE 1

| | Example 6 | Example 8 | Reference Example 1 |
|---|---|---|---|
| Etching Step | 271.8 | 299.2 | 14144 |
| (nm) | | | |
| Etching Rate | 4.5 | 5.0 | 235.7 |
| (nm/min) | | | |
| Dielectric | 10.92 | 10.72 | 4.85 |
| Constant | | | |

Referring to Table 1, it was identified that Examples 6 and 8 including all of SiO₂, Al₂O₃ and SrO and satisfying specific content achieved low etching step and low etching rate, and exhibited high dielectric constant compared to Reference Example 1 made of Quartz.

Accordingly, as the content of SiO₂, Al₂O₃ and SrO of the plasma-resistant glass is satisfied in one embodiment of the present disclosure, thermal shock may be prevented at a high temperature by having a low thermal expansion coefficient while having low etching rate and low glass transition temperature, a low melting temperature may be achieved, and durability may be improved through improving mechanical properties by achieving light transmittance and high hardness.

Hereinbefore, the present disclosure has been described with limited examples, however, the present disclosure is not limited thereto, and it is obvious that various changes and modifications may be made by those skilled in the art within technical ideas of the present disclosure and the range of equivalents of the claims to be described.

What is claimed is:

1. Plasma-resistant glass formed by melting a composition including 30% by weight or greater and 80% by weight or less of SiO₂, 5% by weight or greater and 35% by weight or less of Al₂O₃ and 10% by weight or greater and 50% by weight or less of SrO.

2. The plasma-resistant glass of claim 1, wherein the composition includes only SiO₂, Al₂O₃, SrO and inevitable impurities, the content of the SiO₂ is 30% by weight or greater and 68% by weight or less, the content of the Al₂O₃ is 5% by weight or greater and 25% by weight or less, and the content of the SrO is 15% by weight or greater and 50% by weight or less.

3. The plasma-resistant glass of claim 1, which has light transmittance of 80% or greater and 100% or less.

4. The plasma-resistant glass of claim 1, which has Vickers hardness of 650 HV or greater and 1,000 HV or less.

5. The plasma-resistant glass of claim 1, which has a glass transition temperature of 600° C. or higher and 850° C. or lower.

6. The plasma-resistant glass of claim 1, which has a thermal expansion coefficient of 4.0×10⁻⁶ m/(m° C.) or greater and 6.0×10⁻⁶ m/(m° C.) or less.

7. The plasma-resistant glass of claim 1, which has an etching rate by mixed plasma of fluorine and argon (Ar) of greater than 0 nm/min and 20 nm/min or less.

8. The plasma-resistant glass of claim 1, which has a melting point of 1,500° C. or higher and 1,750° C. or lower.

9. An inner chamber component for a semiconductor manufacturing process manufactured with the plasma-resistant glass of claim 1.

10. The inner chamber component of claim 9, which is any one of a focus ring, an edge ring, a cover ring, a ring shower, an insulator, an EPD window, an electrode, a view port, an inner shutter, an electro static chuck, a heater, a chamber liner, a shower head, a boat for CVD (chemical vapor deposition), a wall liner, a shield, a cold pad, a source head, an outer liner, a deposition shield, an upper liner, an exhaust plate and a mask frame.

11. A method for manufacturing plasma-resistant glass, the method comprising:
melting a composition including 30% by weight or greater and 80% by weight or less of SiO₂, 5% by weight or greater and 35% by weight or less of Al₂O₃ and 10% by weight or greater and 50% by weight or less of SrO; and
cooling the melted composition.

12. The method of claim 11, wherein a melting temperature in the melting of a composition is 1,400° C. or higher and 1,700° C. or lower.

13. A method for manufacturing an inner chamber component for a semiconductor manufacturing process, the method comprising:
melting the plasma-resistant glass of claim 1;
injecting the melted plasma-resistant glass into a mold; and
annealing the injected plasma-resistant glass.

14. The method of claim 13, wherein a melting temperature in the melting of the plasma-resistant glass is 1,500° C. or higher and 1,750° C. or lower.

15. The method of claim 13, wherein a temperature in the annealing is 400° C. or higher and 900° C. or lower.
